(19) United States
(12) Patent Application Publication
(10) Pub. No.: US 2012/0222616 A1
(43) Pub. Date: Sep. 6, 2012

(54) SHOWER HEAD ASSEMBLY AND THIN FILM DEPOSITION APPARATUS COMPRISING SAME

(75) Inventors: Chang-Hee Han, Pyungtaek-Si (KR); Dong-Ho Ryu, Pyungtaek-Si (KR); Ki-Hoon Lee, Pyungtaek-Si (KR)

(73) Assignee: WONIK IPS CO., LTD., Pyeongtaek-Si, Gyeonggi-Do (KR)

(21) Appl. No.: 13/509,986

(22) PCT Filed: Sep. 13, 2010
(86) PCT No.: PCT/KR2010/006206

§ 371 Date: May 15, 2012

(30) Foreign Application Priority Data
Nov. 18, 2009 (KR) 10-2009-0111629

(51) Int. Cl. C23C 16/50; B05B 1/14

(52) U.S. Cl. 118/723 E; 118/723 R; 239/548

(57) ABSTRACT

Provided are a showerhead assembly for depositing a thin film on a substrate and a thin film deposition apparatus having the same. The showerhead assembly includes a plurality of gas injection units radially disposed above a substrate, each of the plurality of gas injection units comprising a receiving part configured to receive a gas supplied from the outside and a plurality of injection holes configured to inject the gas within the receiving part. Here, at least one gas injection unit includes the receiving part defined therein, a showerhead body comprising a first inlet configured to supply a first gas into the receiving part and a second inlet configured to supply a second gas into the receiving part, the showerhead body comprising a plurality of first injection holes and a plurality of second injection holes in a bottom part thereof, wherein the first and second injection holes pass through the bottom part, a partition plate having a flat plate shape and comprising a plurality of insertion holes passing therethrough, the partition plate being disposed facing the bottom plate of the showerhead body in the receiving part of the showerhead body to divide the receiving part into a first buffer part communicating with the first inlet and a second buffer part communicating with the second inlet, a plurality of injection pins, each having a hollow shape, each of the plurality of injection pines comprising one end connected to the insertion hole and the other end connected to the first injection hole, and a power source configured to apply a power to generate plasma within the receiving part of the showerhead body.

### TECHNICAL FIELD

The present disclosure relates to a showerhead assembly for depositing a thin film on a substrate and a thin film deposition apparatus having the same, and more particularly, to a showerhead assembly for depositing a thin film using a reaction gas and a source gas and a thin film deposition apparatus having the same.

### BACKGROUND ART

A semiconductor manufacturing process includes a deposition process for depositing a thin film on a wafer or substrate. An atomic layer deposition apparatus and a chemical vapor deposition apparatus may be used as an apparatus for performing the deposition process.

The atomic layer deposition apparatus is an apparatus in which a source gas, a purge gas, a reaction gas, and a purge gas are successively injected onto a substrate (wafer) to deposit a thin film. The atomic layer deposition apparatus may have an advantage that the thin film can be uniformly deposited on the substrate. However, a rate of deposition is relatively slow.

Also, the chemical vapor deposition apparatus is an apparatus in which a source gas and a reaction gas are injected together onto a substrate to deposit a thin film on the substrate by reaction between the two gases. The chemical vapor deposition apparatus may have an advantage that a rate of thin film deposition is relatively fast when compared to that of the atomic layer deposition apparatus. However, uniformity of the deposited thin film is relatively low.

However, since the atomic layer deposition apparatus (revolver type) according to the related art includes a plurality of single showerheads, the atomic layer deposition apparatus does not realize a chemical vapor deposition process. On the other hand, the chemical vapor deposition apparatus according to the related art includes one dual showerhead. Thus, the chemical vapor deposition apparatus does not realize an atomic layer deposition process. That is, each of the deposition apparatuses according to the related art may realize one deposition process. Thus, to realize all the chemical vapor deposition process and the atomic layer deposition process, the two deposition apparatuses may be individually manufactured.

Furthermore, in case of the chemical vapor deposition apparatus according to the related art, plasma may be generated within a supplied gas to secure a fast reaction rate. However, in this case, there is a limitation that particles generated by the reaction between the source gas and the reaction gas may be accumulated within the apparatus.

### DISCLOSURE

### Technical Problem

The present disclosure provides a showerhead assembly which can realize all atomic layer deposition process and chemical vapor deposition process and have an improved structure to prevent particles from being accumulated within a deposition apparatus when plasma is generated, and a thin film deposition apparatus having the same.

### Technical Solution

In accordance with an exemplary embodiment, a thin film deposition apparatus includes: a chamber having a space part in which a deposition process is performed on a substrate; a susceptor on which the substrate is seated, the susceptor being rotatably disposed in the space part of the chamber; a heater part configured to heat the substrate; and a showerhead assembly.

In accordance with another exemplary embodiment, a showerhead assembly includes: a plurality of gas injection units radially disposed above a substrate, each of the plurality of gas injection units including a receiving part configured to receive a gas supplied from the outside and a plurality of injection holes configured to inject the gas within the receiving part, wherein at least one gas injection unit of the plurality of gas injection units includes: the receiving part defined therein; a showerhead body including a first inlet configured to supply a first gas into the receiving part and a second inlet configured to supply a second gas into the receiving part, the showerhead body including a plurality of first injection holes and a plurality of second injection holes in a bottom part thereof, wherein the first and second injection holes pass through the bottom part; a partition plate having a flat plate shape and including a plurality of insertion holes passing therethrough, the partition plate being disposed facing the bottom plate of the showerhead body in the receiving part of the showerhead body to divide the receiving part into a first buffer part communicating with the first inlet and a second buffer part communicating with the second inlet; a plurality of injection pins, each having a hollow shape, each of the plurality of injection pines including one end connected to the insertion hole and the other end connected to the first injection hole; and a power source configured to apply a power to generate plasma within the receiving part of the showerhead body, wherein the first gas is supplied into the first buffer part and injected onto the substrate through the injection pins, and the second gas is supplied into the second buffer part and injected onto the substrate through the second injection holes.

The showerhead assembly may further include a separation plate having a flat plate shape and including a plurality of flow holes passing therethrough, the separation plate being disposed in the first buffer part to divide the first buffer part into two space parts.

### Advantageous Effects

In accordance with the exemplary embodiments, the atomic layer deposition process and the chemical vapor deposition process may be performed using one apparatus. Thus, economical efficiency and efficiency of the apparatus may be improved, and it may prevent the particles from being accumulated within the apparatus.

### DESCRIPTION OF DRAWINGS

Exemplary embodiments can be understood in more detail from the following description taken in conjunction with the accompanying drawings, in which:

FIG. 1 is a sectional view of a thin film deposition apparatus in accordance with an exemplary embodiment;

FIG. 2 is a plan view of a showerhead assembly illustrated in FIG. 1;

FIG. 3 is a sectional view of a gas injection unit for generating plasma illustrated in FIG. 2;

FIG. 4 is a sectional view of a showerhead gas injection unit in accordance with another exemplary embodiment; and

FIG. 5 is a sectional view of a gas injection unit for generating plasma in according with another exemplary embodiment.

### MODE FOR INVENTION

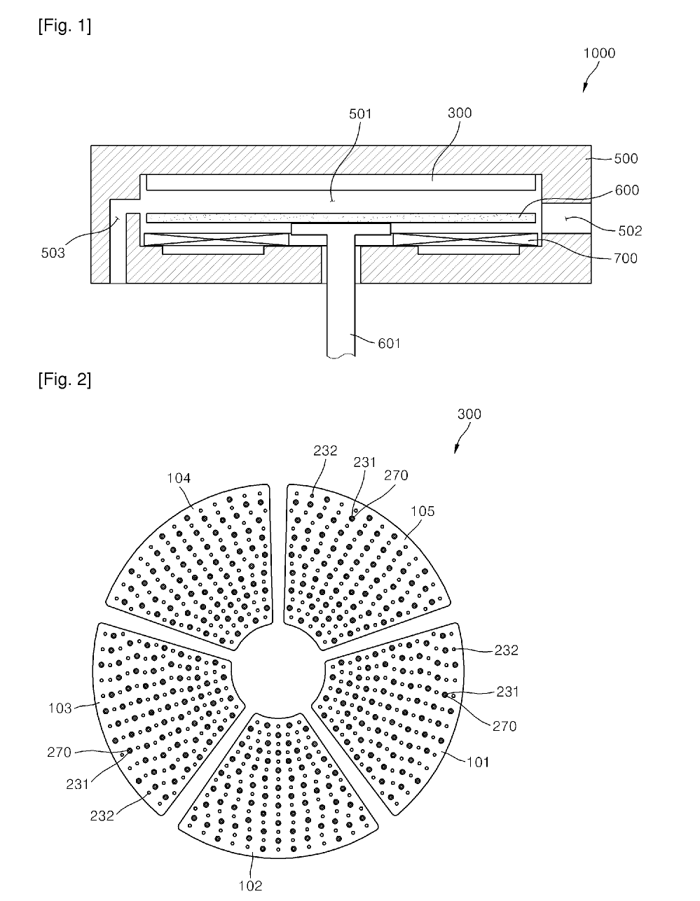

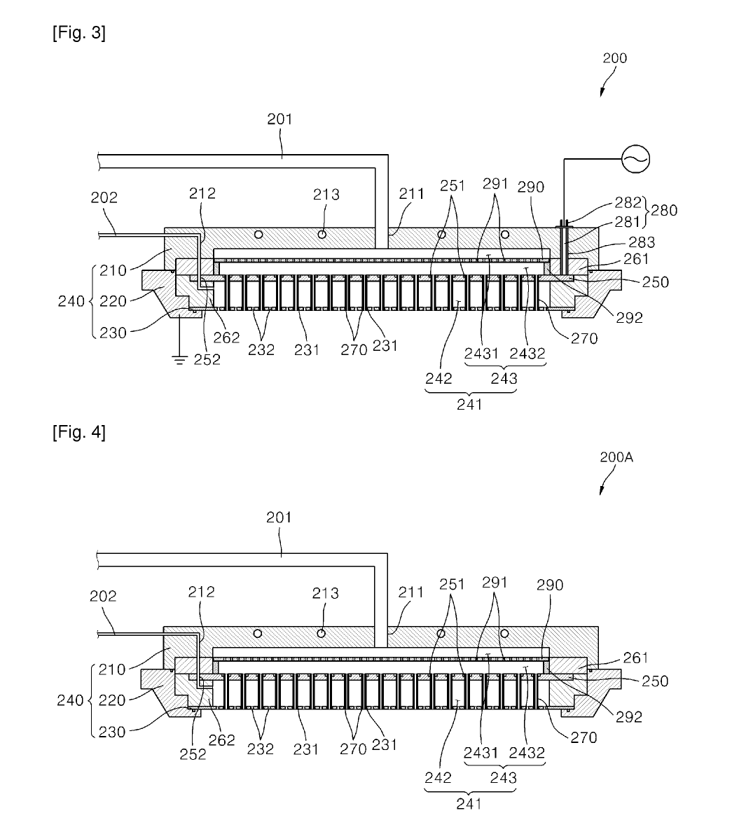

FIG. 1 is a sectional view of a thin film deposition apparatus in accordance with an exemplary embodiment. FIG. 2 is a plan view of a showerhead assembly illustrated in FIG. 1. FIG. 3 is a sectional view of a gas injection unit for generating plasma illustrated in FIG. 2.

Referring to FIGS. 1 to 3, a thin film deposition apparatus 1000 in accordance with an exemplary embodiment includes a chamber 500, a susceptor 600, a heater part 700, and a showerhead assembly 300.

A space part 501 in which a deposition process is performed on a substrate is defined in the chamber 500. Also, the chamber 500 has a gate through which the substrate enters or exits to load/unload the substrate and an exhaust passage 503 for discharging gases within the chamber 500.

The susceptor 600 has a flat plate shape, and the substrate is seated on the susceptor 600. The susceptor 600 is coupled to a driving shaft 601 and disposed in the space part 501 so that the susceptor 600 is elevated and rotated. A plurality of seat parts (not shown) on which substrates are seated are disposed on a top surface of the susceptor 600.

The heater part 700 heats the substrate up to a process temperature. That is, the heater part 700 is disposed under the susceptor 600 to heat the substrate.

The showerhead assembly 300 may be configured to perform all a chemical vapor deposition process (CVD) and atomic layer deposition process (ALD). For this, the showerhead assembly 300 includes a plurality of gas injection units, each having a receiving part and a plurality of injection holes, radially disposed above the susceptor 600. Also, the showerhead assembly 300 includes at least one gas injection unit 200 for generating plasma. In the current embodiment, as shown in FIG. 2, the showerhead assembly 300 includes five gas injection units 101 to 105. All the gas injection units 101 to 105 constitute the gas injection unit 200 for generating plasma.

The gas injection unit 200 for generating plasma may inject two kinds of gases different from each other onto the substrate. The gas injection unit 200 may generate plasma therein. Hereinafter, a structure of the gas injection unit 200 for generating plasma will be described in detail with reference to FIG. 3.

The gas injection unit 200 for generating plasma in accordance with an exemplary embodiment includes a showerhead body 240, a partition plate 250, a plurality of injection pins 270, and a power source 280.

The showerhead body 240 includes an upper plate 210, a lower plate 220, and a bottom plate 230. The upper plate 210 has a first inlet 211 connected to a first gas supply tube 291 through which a first gas is supplied and a second inlet 212 connected to a second gas supply tube 202 through which a second gas is supplied. Here, the first inlet 211 and the second inlet 212 pass through the upper plate 210. A heater 213 is buried in the upper plate. The lower plate 220 has a ring shape and is coupled to a lower end of the upper plate 210. As shown in FIG. 3, the lower plate is grounded. The bottom plate 230 has a plate shape. A plurality of injection holes passes through the bottom plate 230. The injection holes include a plurality of first injection holes 231 and a plurality of second injection holes 232 which are connected to the injection pins 270 that will be described later in detail. The bottom plate 230 corresponds to a bottom part of the showerhead body 240. The bottom plate 230 is coupled to a lower end of the lower plate 220 and disposed within the lower plate 220. Also, the bottom plate 230 together with the upper plate 210 and the lower plate 220 defines a receiving part 241. The bottom plate 230 is electrically connected to the lower plate 220 and grounded.

The partition plate 250 has a flat plate shape. The partition plate 250 has a plurality of insertion holes 251 and a flow hole 252 communicating with the second inlet 212 of the upper plate 210. Here, the insertion holes 251 and the flow holes 252 pass through the partition plate 250. The partition plate 250 is disposed facing the bottom plate 230 within the receiving part 241 to divide the receiving part 241 into a first buffer part 243 and a second buffer part 242. The first buffer layer 243 is disposed above the partition plate 250 to communicate with the first inlet 211. The second buffer part 242 is disposed under the partition plate 250 to communicate with the second inlet 212. As described below, the partition plate 250 may be formed of a conductive material to generate plasma within the receiving part 241.

Also, the partition plate 250 is insulated and supported by a first insulation member 261 and a second insulation member 262. The first insulation member 261 has a circular shape and is coupled to the upper plate 210. The first insulation member 261 has flow holes communicating with the second inlet 212 of the upper plate and the flow hole 252 of the partition plate 250. Here, the flow holes pass through the first insulation member 261. The second insulation member 262 has a circular shape and is coupled to the lower plate 220. The second insulation member 262 has a through hole communicating with the flow hole 252 of the partition plate 250. As shown in FIG. 3, the partition plate 250 is disposed between the first insulation member 261 and the second insulation member 262 to support the first and second insulation members 261 and 262. Thus, the upper plate 210 and the lower plate 220 are electrically insulated from the partition plate 250.

The injection pins 270 are configured to inject the first gas supplied into the first buffer part 243 onto the substrate in a state where the first gas is separated from the second gas supplied into the second buffer part 242. Each of the injection pins 270 has a hollow shape. The injection pin 270 has one end connected (inserted) to the insertion hole 251 of the partition plate 250 and the other end connected (inserted) to the first injection hole 231 of the bottom plate 230. The injection pin 270 may be formed of an insulation material.

The power source 280 applies a power to the partition plate 250 to generate plasma within the receiving part 241. Specifically, in the current embodiment, the power source 280 applies an RF power to the partition plate 250. The power source 280 includes an RF rod 281 and an RF connector 282. The RF rod 281 has a bar shape. Also, the RF rod 281 passes through the upper plate 210 and the first insulation member 261 and is inserted into the upper plate 210 and the first insulation member 261. Also, the RF rod 281 is connected to the partition plate 250. An insulation member 283 is coupled to an outer surface of the RF rod 281. The RF connector 282 is connected to the RF rod 281 to apply the RF power to the RF rod 281.

Also, a separation plate 290 may be disposed within the showerhead body 240. The separation plate 290 has a flat plate shape. Also, a plurality of flow holes 291 pass through the separation plate 290. The separation plate 290 is disposed within the first buffer part 243 to divide the first buffer part 243 into a first space part 2431 and a second space part 2432. A support pin 292 for supporting the separation plate 290 is coupled to each of both sides of the separation plate 290. The first gas introduced through the first inlet 211 is firstly diffused in the first space part 2431. Then, the diffused first gas is introduced into the second space part 2432 through the flow hole 291 and uniformly diffused again in the second space part 2432. Thereafter, the first gas is injected through the injection pin 270. Thus, the first gas is uniformly injected onto the substrate.

In the gas injection unit 200 for generating plasma including the above-described components, the first gas is supplied into the first buffer part 243 through the first gas supply tube 201, and then is injected through the injection pin 270. Also, the second gas is supplied into the second buffer part 242 through the second gas supply tube 202, and then is injected through the second injection hole 232. Here, when the RF power is applied from the power source 280, plasma is generated within the second gas supplied into the second buffer part 242 between the partition plate 250 to which the RF power is applied and the grounded bottom plate 230.

Hereinafter, a process for depositing a SiO₂ thin film using the above-described thin film deposition apparatus 1000 will be described.

First, when an SiO2 thin film is deposited using an atomic layer deposition process, only the fourth gas injection units 101 to 104 for generating plasma of the five gas injection units 101 to 105 for generating plasma are used. That is, a source gas (SiH₄) is supplied into the first gas supply tube (or the second gas supply tube) of the first gas injection unit 101 for generating plasma, and a reaction gas (O₂) is supplied into the first gas supply tube (or the second gas supply tube) of the third gas injection unit 103 for generating plasma. Also, a purge gas is supplied into the first gas supply tube (or the second gas supply tube) of the second and fourth gas injection units 102 and 104 for generating plasma.

In a state where the susceptor 600 on which the substrate is seated is rotated, as described above, when the source gas, the reaction gas, and the purge gas are respectively injected from the first to fourth gas injection units 101 to 104 for generating plasma, the source gas, the purge gas, the reaction gas, and the purge gas are injected on the substrate in order of precedence. Thus, a thin film is deposited on the substrate. Also, as necessary, when the RF power is applied to the partition plate 250 of the third gas injection unit 103 for generating plasma, plasma is generated within the reaction gas supplied into the second buffer part (in the case, the reaction gas should be supplied into the second gas supply tube). Thus, a rate of deposition may be improved.

When a thin film is deposited using a chemical vapor deposition process, a source gas is supplied into the first gas supply tube 201 of each of the gas injection units 101 to 105 for generating plasma, and a reaction gas is supplied into the second gas supply tube 202 (alternatively, the source gas may be supplied into the second gas supply tube 202, and the reaction gas may be supplied into the first gas supply tube 201). In a state where the substrate is seated on the susceptor 600, when the source gas and the reaction gas are injected together from the gas injection unit for generating plasma, a thin film is deposited on the substrate by the chemical vapor deposition process. Also, as necessary, when the RF power is applied to the partition plate 250 of the gas injection unit 200 for generating plasma, plasma is generated within the reaction gas supplied into the second buffer part. Thus, a rate of deposition may be improved. Here, although the plasma is generated in the reaction gas within the second buffer part, the reaction gas and the source gas are mixed after the gases are injected to the outside of the gas injection unit for generating plasma. Thus, it may prevent particles generated by reaction between the source gas and the reaction gas from being deposited or accumulated within the gas injection unit for generating plasma. When the chemical vapor deposition process is performed, only a portion of the gas injection units for generating plasma may be used, but all the five gas injection units for generating plasma are not used.

When the thin film deposition apparatus 1000 in accordance with an exemplary embodiment is used, all the atomic layer deposition process and the chemical vapor deposition process may be performed in one process.

In this case, that is, the source gas is supplied into the gas supply tube of the first gas injection unit 101 for generating plasma, the reaction gas is supplied into the gas supply tube of the third gas injection unit 103 for generating plasma, the purge gas is supplied into the gas supply tube of the second and fourth gas injection units 102 and 104 for generating plasma, and the source gas and the reaction gas are supplied into the gas supply tube of the fifth gas injection unit 105 for generating plasma.

In this state, in an initial process of the thin film deposition process, when a gas is not injected from the fifth gas injection unit 105 for generating plasma, and a corresponding gas is injected from only the first to fourth gas injection units 101 and 104 for generating plasma while rotating the susceptor 600, the thin film may be very uniformly deposited on the substrate through the atomic layer deposition process.

Thereafter, when the gas injection through the first to fourth gas injection units 101 to 104 for generating plasma is stopped, and the source gas and the reaction gas are injected together from the fifth gas injection unit 105 for generating plasma (here, the substrate is disposed under the fifth gas injection unit 105 for generating plasma), a thin film may be quickly deposited on the substrate by the chemical vapor deposition process.

Here, uniformity of the deposited and grown thin film may be largely affected by uniformity of the thin film (that is, an area which is called a seed layer) initially deposited on the substrate. Thus, as described above, in the initial process, the thin film is deposited using the atomic layer deposition process. Then, after the seed layer is grown somewhat, the thin film is deposited using the chemical vapor deposition process. Thus, the thin film may be uniformly and quickly deposited.

In the forgoing embodiment, although all the gas injection units are constituted by the gas injection units for generating plasma, the present disclosure is not limited thereto. For example, three gas injection units 101, 103, and 105 may be constituted by the gas injection units for generating plasma, and other two gas injection units 102 and 104 may be constituted by a dual showerhead gas injection unit 200A illustrated in FIG. 4.

Comparing FIG. 4 to FIG. 3, a dual showerhead gas injection unit 200A has the same configuration as that of the gas injection unit 200 for generating plasma. However, the dual showerhead gas injection unit 200A is different from the gas injection unit 200 for generating plasma in that a power source for generating plasma is not provided. Also, the dual showerhead gas injection unit 200A may be used for injecting a gas (e.g., a purge gas) in which the plasma is not generated.

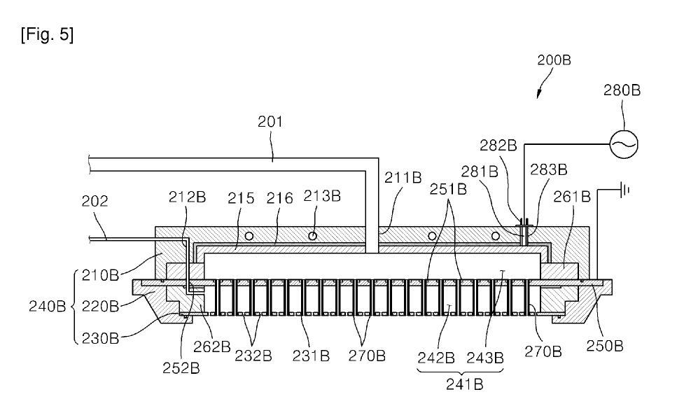

Alternatively, a gas injection unit for generating plasma may be configured as shown in FIG. 5 to generate plasma in a first buffer part. FIG. 5 is a sectional view of a gas injection unit 200B for generating plasma in according with another exemplary embodiment. Referring to FIG. 5, the gas injection unit 200B for generating plasma according to the current embodiment includes a showerhead body 240B, an electrode plate 215, a partition plate 250B, a plurality of injection pins 270B, and a power source 280B.

The showerhead body 240B includes an upper plate 210B, a lower plate 220B, and a bottom plate 230B. The upper plate 210B has a first inlet 211B and a second inlet 212B. Here, the first and second inlets 211B and 212B pass through the upper plate 210B. Also, a heater 213B is buried in the upper plate 210B. The electrode plate 215 having a flat plate shape is coupled to a lower portion of the upper plate 210B. An insulation member 216 is disposed between an insulation plate for insulating the electrode plate 215 from the upper plate 210B and the upper plate 210B. The lower plate 220B has a ring shape and is coupled to a lower end of the upper plate 210B. The bottom plate 230B has a plate shape. The bottom plate 230B has a plurality of first injection holes 231B and a plurality of second injection holes 232B. Here, the first and second injection holes 231B and 232B pass through the bottom plate 230B. The bottom plate 230b corresponds to a bottom part of the showerhead body 240B and is coupled to a lower end of the lower plate 220B.

The partition plate 250B has a flat plate shape. The partition plate 250 has a plurality of insertion holes 251B and a flow hole 252B. Here, the insertion holes 251B and the flow holes 252B pass through the partition plate 250B. The partition plate 250B is disposed facing the bottom plate 230B and the electrode plate 215 within the receiving part 241B to divide the receiving part 241B into a first buffer part 243B and a second buffer part 242B. The first buffer layer 243B is disposed above the partition plate 250B to communicate with the first inlet 211B. The second buffer part 242B is disposed under the partition plate 250B to communicate with the second inlet 212B. Also, the partition plate 250B is insulated and supported by a first insulation member 261B and a second insulation member 262B. The partition plate 250B is grounded.

The injection pins 270B are configured to inject a first gas supplied into the first buffer part 243B onto a substrate in a state where the first gas is separated from a second gas supplied into the second buffer part 242B. Each of the injection pins 270B has a hollow shape. The injection pin 270B has one end connected (inserted) to the insertion hole 251B of the partition plate 250B and the other end connected (inserted) to the first injection hole 231B of the bottom plate 230B. The injection pin 270B may be formed of an insulation material.

The power source 280B applies a power to the partition part 215 to generate plasma within the first buffer part 243B. Specifically, in the current embodiment, the power source 280B applies an RF power to the partition plate 250B. The power source 280B includes an RF rod 281B and an RF connector 282B. The RF rod 281B has a bar shape. Also, the RF rod 281B passes through the upper plate 210B and the insulation member 216 and is inserted into the upper plate 210B and the insulation member 216. Also, the RF rod 281B is connected to the electrode plate 215. An insulation member 283B is coupled to an outer surface of the RF rod 281B. The RF connector 282B is connected to the RF rod 281B to apply the RF power to the RF rod 281B. The RF power is applied to the electrode plate 215 to generate plasma between the grounded partition plate 250B and the electrode plate 215, i.e., in the first buffer part 243B.

Although the showerhead assembly and the thin film deposition apparatus having the same have been described with reference to the specific embodiments, they are not limited thereto. Therefore, it will be readily understood by those skilled in the art that various modifications and changes can be made thereto without departing from the spirit and scope of the present invention defined by the appended claims.

For example, although the showerhead assembly includes the five gas injection units having the same injection area (size) in the foregoing embodiments, the number of gas injection units, the injection area, and the disposition configurations of the gas injection units may be optimally changed according to characteristics of the thin film deposition process.

What is claimed is:

1. A showerhead assembly comprising:
a plurality of gas injection units radially disposed above a substrate, each of the plurality of gas injection units comprising a receiving part configured to receive a gas supplied from the outside and a plurality of injection holes configured to inject the gas within the receiving part,
wherein at least one gas injection unit of the plurality of gas injection units comprises:
the receiving part defined therein;
a showerhead body comprising a first inlet configured to supply a first gas into the receiving part and a second inlet configured to supply a second gas into the receiving part, the showerhead body comprising a plurality of first injection holes and a plurality of second injection holes in a bottom part thereof, wherein the first and second injection holes pass through the bottom part;
a partition plate having a flat plate shape and comprising a plurality of insertion holes passing therethrough, the partition plate being disposed facing the bottom plate of the showerhead body in the receiving part of the showerhead body to divide the receiving part into a first buffer part communicating with the first inlet and a second buffer part communicating with the second inlet;
a plurality of injection pins, each having a hollow shape, each of the plurality of injection pines comprising one end connected to the insertion hole and the other end connected to the first injection hole; and
a power source configured to apply a power to generate plasma within the receiving part of the showerhead body,
wherein the first gas is supplied into the first buffer part and injected onto the substrate through the injection pins, and the second gas is supplied into the second buffer part and injected onto the substrate through the second injection holes.

2. The showerhead assembly of claim 1, further comprising a separation plate having a flat plate shape and comprising a plurality of flow holes passing therethrough, the separation plate being disposed in the first buffer part to divide the first buffer part into two space parts.

3. The showerhead assembly of claim 1, wherein an electrode plate is coupled to an upper end of the showerhead body to face the partition plate,
the power source applies a power to the electrode plate to generate plasma in the first buffer part, and
the partition plate is grounded.

4. The showerhead assembly of claim 1, wherein the power source applies a power to the partition plate to generate plasma in the second buffer part, and
the bottom part of the showerhead body is grounded.

5. A thin film deposition apparatus comprising:
a chamber having a space part in which a deposition process is performed on a substrate;
a susceptor on which the substrate is seated, the susceptor being rotatably disposed in the space part of the chamber;
a heater part configured to heat the substrate; and
the showerhead assembly of any one of claims 1 to 4.
